(19) United States
(12) Patent Application Publication
(10) Pub. No.: US 2025/0379063 A1
(43) Pub. Date: Dec. 11, 2025

(54) ETCH BACK FOR ENHANCED DIRECTIONAL DEPOSITION

(71) Applicant: Applied Materials, Inc., Santa Clara, CA (US)

(72) Inventors: ZHIYU HUANG, Sunnyvale, CA (US); CHARITH NANAYAKKARA, Rowley, MA (US); SWASTI BHATIA, Gloucester, MA (US); MADHUR SACHAN, Belmont, CA (US); JOHN HAUTALA, Beverly, MA (US)

(21) Appl. No.: 19/213,874

(22) Filed: May 20, 2025

Related U.S. Application Data
(60) Provisional application No. 63/658,372, filed on Jun. 10, 2024.

(51) Int. Cl. H01L 21/311

(52) U.S. Cl. CPC H01L 21/31116

(57) ABSTRACT

Embodiments described herein relate to a method that includes forming a pattern in a first layer of a substrate, where the pattern has a first critical dimension (CD) in a first axis and a second CD in a second axis, and where the first CD is different than the second CD. In an embodiment, the method further includes depositing a second layer over the first layer with a directional deposition process, and etching the second layer, where a first etch rate of the second layer in a first direction of the first axis is different than a second etch rate of the second layer in a second direction.

### CROSS-REFERENCE TO RELATED APPLICATIONS

This application claims the benefit of U.S. Provisional Application No. 63/658,372, filed on Jun. 10, 2024, the entire contents of which are hereby incorporated by reference herein.

### BACKGROUND

### 1) Field

Embodiments of the present disclosure pertain to the field of directional deposition improvements through the use of an etch back process.

### 2) Description of Related Art

In semiconductor processing, careful control of the placement and/or shape of patterned structures is necessary to provide high yielding devices. In some semiconductor structures, holes, trenches, and/or the like are formed into a layer. For example, an etching process may be used in order to generate such structures in the layer. Continued advances in technology keep driving these features to have smaller critical dimensions (CDs). At some point, the CDs of the features may exceed the capability of existing lithography and patterning technology available for fabricating certain semiconductor devices. Additional reductions of CD can be implemented through layer deposition processes that modify the originally patterned structure. For example, directional deposition processes have the capability for pattern shaping in order to shrink the CD of a device in a particular dimension. Directional deposition may also allow for improvements in edge placement error (EPE), since a particular edge of a patterned feature can be “moved” through directionally depositing a second layer over the edge.

### SUMMARY

Embodiments described herein relate to a method that includes forming a pattern in a first layer of a substrate, where the pattern has a first critical dimension (CD) in a first axis and a second CD in a second axis, and where the first CD is different than the second CD. In an embodiment, the method further includes depositing a second layer over the first layer with a directional deposition process, and etching the second layer, where a first etch rate of the second layer in a first direction of the first axis is different than a second etch rate of the second layer in a second direction.

Embodiments described herein relate to a method that includes forming a pattern in a first layer of a substrate, and depositing a second layer over the first layer with a directional deposition process, where the second layer has a first thickness along a first sidewall portion of the pattern and a second thickness along a second sidewall portion of the pattern, and where the first thickness is greater than the second thickness. In an embodiment, the method further includes etching the second layer so that the second layer is completely removed from the second sidewall portion of the pattern while still remaining on the first sidewall portion of the pattern.

Embodiments described herein relate to a method that includes depositing a second layer over a first layer, where a hole is in the first layer, and where the second layer has a non-uniform thickness along a sidewall perimeter of the hole. In an embodiment, the method further includes etching the second layer with a reactive ion etching (RIE) process, where the second layer is cleared from a first portion of the sidewall of the hole, and where a second portion of the sidewall of the hole remains covered by the second layer.

### BRIEF DESCRIPTION OF THE DRAWINGS

FIG. 1A is a plan view illustration of a layer of a substrate with a patterned feature in the layer, in accordance with an embodiment.

FIG. 1B is a plan view illustration of the layer during a directional deposition process to form a second layer along sidewalls of the patterned feature, in accordance with an embodiment.

FIG. 1C is a cross-sectional illustration of the layer in a direction of the deposition, in accordance with an embodiment.

FIG. 1D is a cross-sectional illustration of the layer in a direction orthogonal to the direction of the deposition, in accordance with an embodiment.

FIG. 2A is a plan view illustration of a layer of a substrate with a patterned feature with a first critical dimension (CD) and a second CD, in accordance with an embodiment.

FIG. 2B is a plan view illustration of the layer with a second layer deposited along sidewalls of the patterned feature, in accordance with an embodiment.

FIG. 2C is a plan view illustration of the layer after an etching process preferentially removes the second layer in one direction, in accordance with an embodiment.

FIGS. 3A-3E are cross-sectional illustrations (in the X-plane and the Y-plane) that show a process for preferentially reducing a CD of a patterned feature in one dimension, in accordance with an embodiment.

FIGS. 4A-4D are plan view illustrations that show a process for repeating a selective layer deposition process in order to provide enhanced CD reduction in a single direction, in accordance with an embodiment.

FIG. 5 is a process flow diagram of a process for reducing a CD of a patterned feature in a single direction, in accordance with an embodiment.

FIG. 6 illustrates a block diagram of an exemplary computer system of a processing tool, in accordance with an embodiment of the present disclosure.

### DETAILED DESCRIPTION

Improved directional deposition with etch back processes are disclosed herein, in accordance with various embodiments. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, directional deposition has the potential to significantly improve patterning processes. For example, directional deposition processes may be used to reduce critical dimensions (CDs) of structures beyond what is possible with existing lithography and patterning tools and processes. Additionally, directional deposition processes may allow for reductions in edge placement error (EPE). However, some directional deposition processes are limited by the ability to control the directionality of the deposited species (sometimes referred to as the beam). Ideally, the beam will have a directional component that is parallel to the desired direction of deposition. For example, if deposition is desired along a surface orthogonal to the X-direction, then the beam should have a directional component that is also primarily in the X-direction. In practice, deposition may also occur along sidewalls orthogonal to the Y-direction due to non-ideal conditions, such as non-optimal process environments, incoming structures with imperfections, and/or the like.

In some instances, the selectivity of the directional deposition may be determined as a change in the CD of the desired direction divided by the change in the CD of the undesired direction. For example, if selective deposition is desired in the X-direction, then the selectivity of the directional deposition may be Δ(X CD)/Δ(Y CD). Existing directional deposition processes may include a selectivity that is up approximately 3, approximately 5, or approximately 10.

Accordingly, embodiments disclosed herein include an etching process that can be combined with the directional deposition process in order to significantly enhance the selectivity of the directional deposition. In some instances, the selectivity of embodiments disclosed herein may be increased to approximately 10 or more, approximately 100 or more, or approximately 1,000 or more. More specifically, the addition of the etching process disclosed herein to the directional deposition may render the directional deposition perfectly selective. That is, the change in CD may only be present in the desired direction while there is zero change in CD in the direction orthogonal to the desired direction.

In an embodiment, the directional deposition and etching process may be implemented as a single cycle in order to provide the desired results. In other embodiments, a plurality of cycles may be provided in order to provide the desired result. The directional deposition and etching process may be applicable to many different types of patterned features, such as holes that are oblong, oval, elliptical, circular, rectangular, square, and/or the like. Patterned features may also include trenches or the like.

In an embodiment, the etching process may include a reactive ion etching (RIE) process. The RIE process may experience preferential loading due to the geometry of the patterned feature. For example, sidewalls that have more open area will etch faster than the sidewalls that are more closed off. Leveraging the uneven etch rate can result in residual material on the undesired portion of the sidewall being etched completely away while the material on the desired portion of the sidewall is only partially etched.

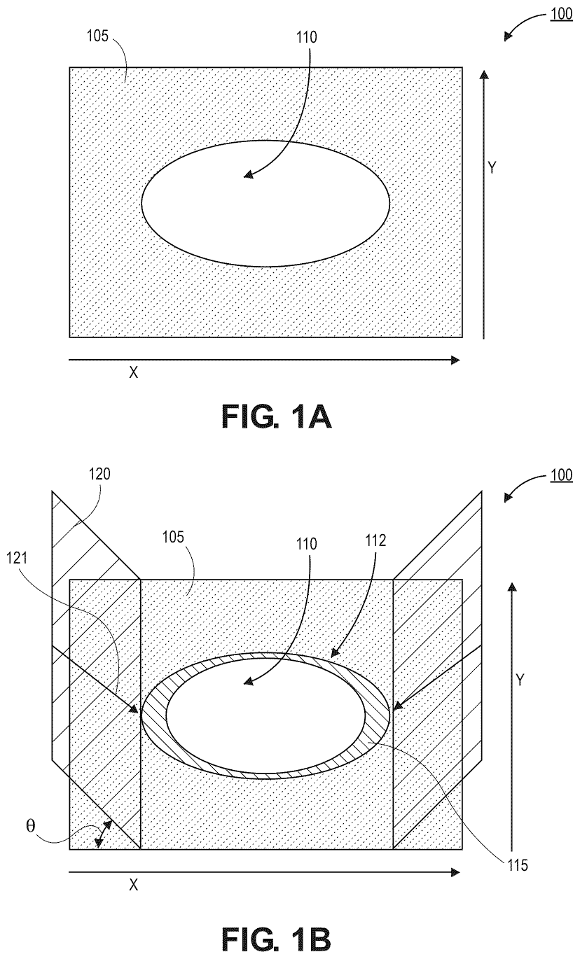

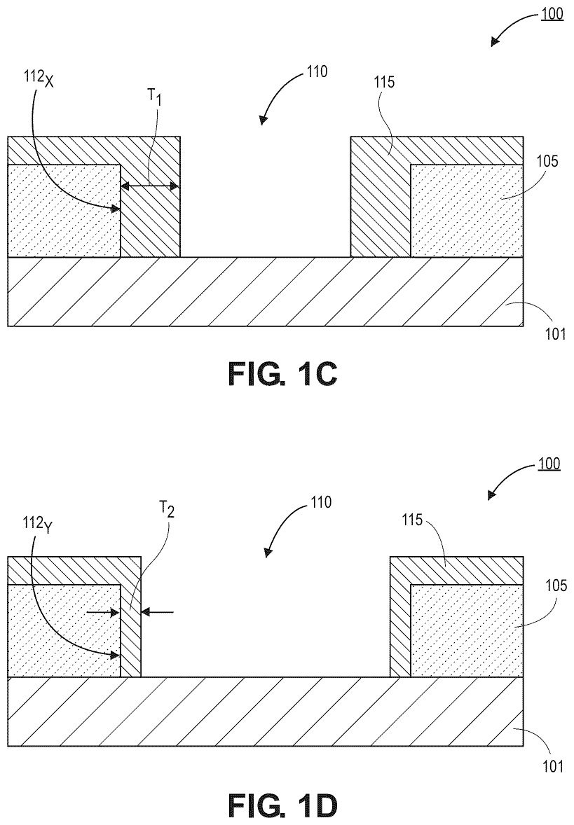

Referring now to FIGS. 1A-1D, a series of illustrations that depict a process for preferentially depositing material on a sidewall of a patterned feature with a directional deposition process is shown, in accordance with an embodiment. In the embodiments shown in FIGS. 1A-1D, the substrate 100 comprises a layer 105 that includes a patterned feature 110. The patterned feature 110 may be formed with any suitable lithography and etching process.

Referring now to FIG. 1A, a plan view illustration of the substrate 100 is shown, in accordance with an embodiment. In an embodiment, the substrate 100 may comprise a semiconductor substrate, such as a silicon wafer or the like. In an embodiment, a layer 105 is provided over an underlying layer (not visible in FIG. 1A). The layer 105 may comprise any suitable pattern transfer layer, such as one comprising carbon, silicon oxide, silicon nitride, silicon oxynitride, or the like. In other embodiments, the layer 105 may comprise a plurality of individual layers. For example, the first layer may comprise a carbon layer and an overlying second layer may comprise silicon, oxygen, and nitrogen (e.g., SiON).

In an embodiment, a patterned feature 110 is provided through a thickness of the layer 105. The patterned feature 110 may be a hole that passes through a thickness of the layer 105. In the particular embodiment shown in FIG. 1A, the patterned feature 110 is an oval shaped hole with a length (in the X direction) that is larger than a width (in the Y-direction). Though, the patterned feature 110 may also be circular, oblong, rectangular, square, or any other suitable shape. In some embodiments, the patterned feature 110 has a length that is different than a width.

Referring now to FIG. 1B, a plan view illustration of the substrate 100 during a directional deposition process is shown, in accordance with an embodiment. As shown, a directional deposition process may include beams 120 that are oriented at an angle θ relative to the surface of the layer 105. The angle θ of the beams allows for deposition of a second layer 115 along the sidewalls 112 of the patterned feature 110. Deposition of the layer 105 may also be provided over the top surface of the layer 105 (but is not shown for clarity). In an embodiment, the directional deposition process may be any suitable type of deposition, such as a physical vapor deposition process (PVD), chemical vapor deposition (CVD), or the like.

In an embodiment, the beams 120 have a directional component 121 that is substantially parallel to the desired direction of deposition. For example, in FIG. 1B, the deposition is desired on a sidewall 112 of the patterned feature 110 that is orthogonal to the X-direction, and the directional component 121 is primarily in the X-direction. However, deposition may also occur along sidewalls orthogonal to the Y-direction due to non-ideal conditions, such as non-optimal process environments, incoming structures with imperfections, and/or the like. For example, the second layer 115 may be thicker along the left and right sidewalls 112 of the patterned feature 110 (as viewed in FIG. 1B) than along the top and bottom sidewalls 112 of the patterned feature 110 (as viewed in FIG. 1B).

Referring now to FIG. 1C, a cross-sectional illustration of the substrate 100 along a plane parallel to the X-direction through a center of the patterned feature 110 is shown, in accordance with an embodiment. As shown, the second layer 115 is provided over the top surface of the layer 105 and along the sidewalls 112_{X} of the patterned feature 110. While the underlying layer 101 is uncovered in the remainder of the opening of the patterned feature 110, other embodiments may include a directional deposition process that covers the underlying layer 101 as well. In an embodiment, the second layer 115 May have a first thickness T₁ along the sidewalls 112_{X}. The first thickness T₁ may be relatively thick (e.g., compared to other sidewall portions of the patterned feature 110) due to the larger percentage of the directional components 121 that are aligned with the X-direction.

Referring now to FIG. 1D, a cross-sectional illustration of the substrate 100 along a plane parallel to the Y-direction through a center of the patterned feature 110 is shown, in accordance with an embodiment. As shown, the second layer 115 is provided over the top surface of the layer 105 and along the sidewalls 112_{Y} of the patterned feature 110. While the underlying layer 101 is uncovered in the remainder of the opening of the patterned feature 110, other embodiments may include a directional deposition process that covers the underlying layer 101 as well. In an embodiment, the second layer 115 may have a second thickness T₂ along the sidewalls 112_{Y}. The second thickness T₂ may be relatively thin (e.g., compared to the first thickness T₁ of the second layer 115 on the sidewalls 112_{X}) due to process non-uniformities that allow for small deposits on the unintended sidewalls 112_{Y}. In an embodiment, the ratio of the first thickness T₁ to the second thickness T₂ may be up to approximately 2:1 or up to approximately 3:1.

Accordingly, a directional deposition process by itself (as described with respect to FIGS. 1A-1D) may not provide the desired selectivity. In order to improve the selectivity of the directional deposition process, embodiments may further comprise an etching process. In some instances, the etching process may also be selective in order to increase the overall selectivity of the directional deposition (e.g., to 10:1 or greater, 100:1 or greater, 1,000:1 or greater, or even a truly 100% selective directional deposition).

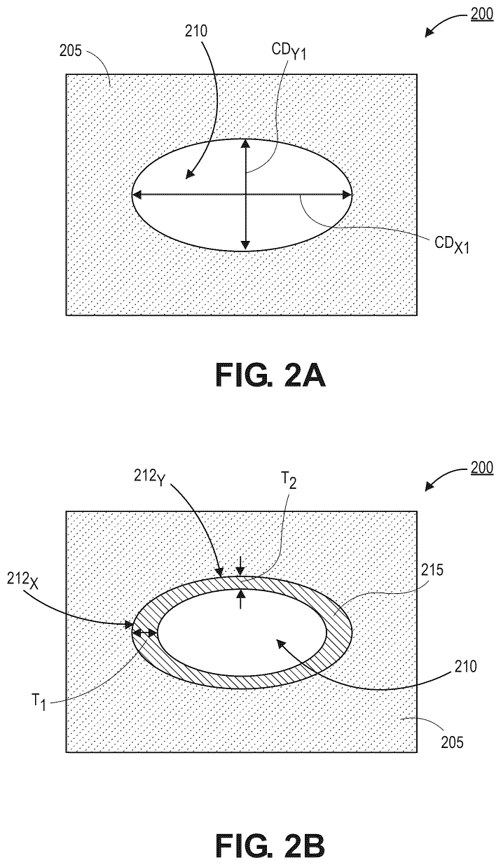

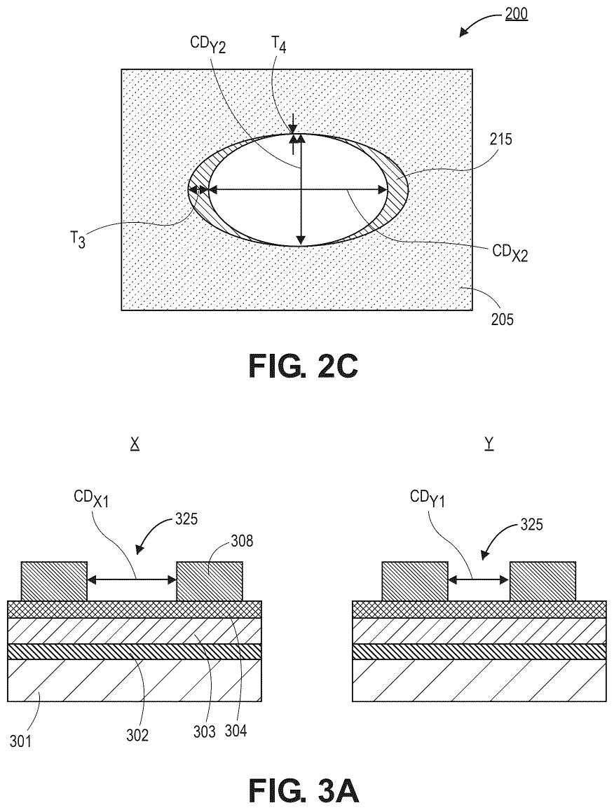

Referring now to FIGS. 2A-2C, a series of plan view illustrations depicting a directional deposition process with a desired selectivity is shown, in accordance with an embodiment. In an embodiment, FIGS. 2A-2C include a substrate 200 with a layer 205 that includes a patterned feature 210. The patterned feature 210 may be formed with any suitable lithography and etching process.

Referring now to FIG. 2A, a plan view illustration of the substrate 200 is shown, in accordance with an embodiment. In an embodiment, the substrate 200 may comprise a semiconductor substrate, such as a silicon wafer or the like. In an embodiment, a layer 205 is provided over an underlying layer (not visible in FIG. 2A). The layer 205 may comprise any suitable pattern transfer layer, such as one comprising carbon or the like. In other embodiments, the layer 205 may comprise a plurality of individual layers. For example, the first layer may comprise a carbon layer and an overlying second layer may comprise silicon, oxygen, and nitrogen (e.g., SiON).

In an embodiment, a patterned feature 210 is provided through a thickness of the layer 205. The patterned feature 210 may be a hole that passes through a thickness of the layer 205. In the particular embodiment shown in FIG. 2A, the patterned feature 210 is an oval shaped hole with a first CD (CD_{X1}) that is larger than a second CD (CD_{Y1}). Though, the patterned feature 210 may also be circular, oblong, rectangular, square, or any other suitable shape. In an embodiment, the first CD (CD_{X1}) is in a direction that is substantially orthogonal to a direction of the second CD (CD_{Y1}). The use of the selective deposition process may be used in order to shrink the first CD while leaving the second CD substantially unchanged.

Referring now to FIG. 2B, a plan view illustration of the substrate 200 after a directional deposition process is shown, in accordance with an embodiment. In an embodiment, the directional deposition process is selective to the X-direction. As such, the second layer 215 is deposited along the sidewalls 212_{X} at a faster rate than the second layer 215 is deposited along the sidewalls 212_{Y}. The directional deposition process in FIG. 2B may be similar to the directional deposition process described in greater detail herein with respect to FIG. 1B. As shown, the second layer 215 may have a first thickness T₁ along the sidewalls 212_{X}, and the second layer 215 may have a second thickness T₂ along the sidewalls 212_{Y}. That is, the thickness of the second layer 215 along the entire sidewall perimeter of the patterned feature 210 may be non-uniform.

Referring now to FIG. 2C, a plan view illustration of the substrate 200 after a preferential etching process is shown, in accordance with an embodiment. In an embodiment, the etching process may result in the preferential removal of the second layer 215 along the sidewalls 212_{Y}. That is, the second layer 215 along the sidewalls 212_{Y} may be etched at a rate that is faster than the etch rate of the second layer 215 along the sidewalls 212_{X}. In an embodiment, a third thickness T₃ of the second layer 215 along the sidewalls 212_{X} may be smaller than the first thickness T₁, and the fourth thickness T₄ along the sidewalls 212_{Y} may be smaller than the second thickness T₂. In some embodiments, the fourth thickness T₄ may be substantially zero (i.e., the second layer 215 may be completely removed from the sidewalls 212_{Y}).

In an embodiment, the ratio of the first thickness T₁ to the second thickness T₂ may be smaller than a ratio of the third thickness T₃ to the fourth thickness T₄. In the case of the complete removal of the second layer 215 from the sidewalls 212_{Y}, the ratio of the third thickness T₃ to the fourth thickness T₄ may be infinite. That is, the overall selectivity of the directional deposition process may be essentially perfect or 100% in the desired direction of deposition.

In an embodiment, the etching process may be an RIE process. The use of an RIE process may be beneficial for providing the desired preferential etching due to the inherent loading effects present in RIE processes. Generally, a surface that is more open will etch at a faster rate than an area that is more closed off. Since the surface of sidewalls 212_{Y} (i.e., the wide side of the oval) have a more gentle curvature compared to the curvature of the surface of sidewalls 212_{X} (i.e., the narrow side of the oval), the second layer 215 on the sidewalls 212_{Y} will etch away faster than the second layer 215 on the sidewalls 212_{X}.

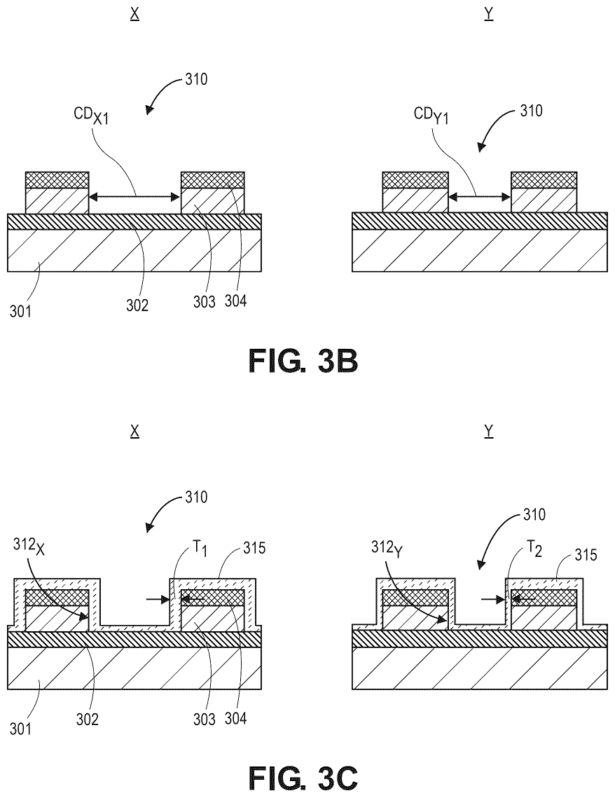

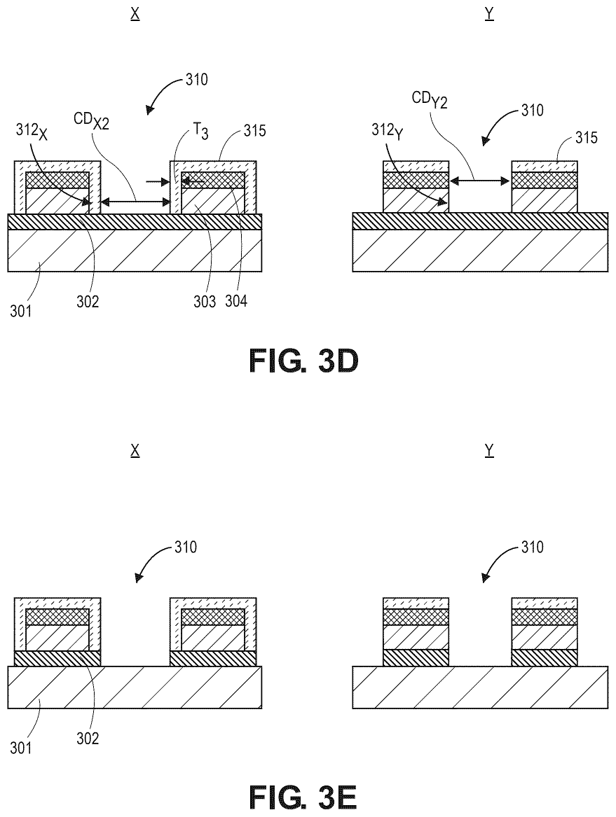

Referring now to FIGS. 3A-3E, a series of cross-sectional illustrations depicting a process for directional deposition with a preferential etch back process is shown, in accordance with an embodiment. In each of the FIGS. 3A-3E, a pair of cross-sections are shown. The cross-section on the left is along a plane that is parallel to the X-direction, and the cross-section on the right is along a plane that is parallel to the Y-direction.

Referring now to FIG. 3A, cross-sectional illustrations of a substrate are shown, in accordance with an embodiment. In an embodiment, the substrate may comprise a layer 301 and overlying patterning layers 302-304 that are arranged in a vertical stack. The layer 301 may be the layer in which the pattern is desired to be transferred. That is, the layer 301 may persist into a final device structure in some embodiments. For example, the layer 301 may be a semiconductor layer, such as silicon, an oxide, a nitride, a metal, and/or the like. The patterning layers 302-304 may include any type of layers suitable for transferring a pattern into the layer 301. The patterning layers 302-304 may ultimately be removed after the pattern transfer into the layer 301 is complete. The patterning layers may comprise a silicon layer 302, a carbon layer 303, and a layer 304 comprising silicon, oxygen, and nitrogen (e.g., SiON). Though, it is to be appreciated that more or fewer layers may be used for pattern transfer, and any suitable materials may be used for such layers.

In an embodiment, the substrates may also comprise a photoresist 308 over the patterning layer 304. The photoresist 308 may be patterned to form an opening 325. The opening 325 may be formed with an exposure and developing process. In an embodiment, the opening 325 may have a shape that is substantially similar to the desired shape that is to be transferred into the layer 301. In the X-cross-section, the opening 325 may have a first CD (CD_{X1}), and in the Y-cross-section, the opening 325 may have a second CD (CD_{Y1}). In some embodiments, the first CD may be different than the second CD. For example, the first CD is larger than the second CD in FIG. 3A. In a plan view, the shape of the opening 325 may be oblong, elliptical, circular, rectangular, square, or the like.

Referring now to FIG. 3B, cross-sectional illustrations depicting the substrate after the opening 325 is transferred into one or more of the patterning layers 302-304 are shown, in accordance with an embodiment. For example, the opening 325 is transferred into the layer 303 and the layer 304. The resulting layers 303 and 304 may have a patterned feature 310 that substantially matches the shape of the opening 325 in the photoresist 308. For example, the patterned feature 310 may have a first CD (CD_{X1}) in the X-cross-section, and the patterned feature 310 may have a second CD (CD_{Y1}) in the Y-cross-section.

Referring now to FIG. 3C, cross-sectional illustrations of the substrate after a directional deposition of a second layer 315 are shown, in accordance with an embodiment. In an embodiment, the directional deposition may be preferential to the X-direction. As such, the second layer 315 may have a first thickness T₁ along sidewalls 312_{X} that is larger than a second thickness T₂ along sidewalls 312_{Y}. The second layer 315 may also be deposited over the exposed surfaces of the layers 302, 303, and 304. In an embodiment, the directional deposition process may be similar to the directional deposition process described in greater detail herein with respect to FIG. 1B.

Referring now to FIG. 3D, cross-sectional illustrations of the substrate after a preferential etching process are shown, in accordance with an embodiment. In an embodiment, the preferential etching process may be an RIE process, such as those described in greater detail herein. Since the sidewalls 312_{Y} of the patterned feature 310 are more open (i.e., part of the wide edge of the patterned feature 310), the second layer 315 will etch faster compared to the second layer 315 on the sidewalls 312_{X} of the patterned feature 310 (i.e., part of the narrow edge of the patterned feature 310). Accordingly, the second layer 315 may have a third thickness T₃ along the sidewalls 312_{X} that (while smaller than the first thickness T₃) is still present. In contrast, the second layer 315 on the sidewalls 312_{Y} may be completely removed.

However, complete removal of the second layer 315 on the sidewalls 312_{Y} is not necessary for all embodiments. Instead, it may be sufficient that a ratio of the first thickness T₁ to the second thickness T₂ is smaller than a ratio of the third thickness T₃ to a remaining thickness of the second layer 315 on the sidewalls 312_{Y}. More generally, a change from the first CD (CD_{X1}) to the third CD (CD_{X2}) may be larger than the change from the second CD (CD_{Y1}) to the fourth CD (CD_{Y2}). For example, the resulting ratio of the change in CDs in the X-direction and the Y-direction after the preferential etching process may be approximately 10:1 or greater, approximately 100:1 or greater, or approximately 1,000:1 or greater.

Referring now to FIG. 3E, cross-sectional illustrations of the substrate after additional pattern transfer into patterning layer 302 are shown, in accordance with an embodiment. The patterned feature 310 may be transferred into the patterning layer 302 with an etching process or the like. In some embodiments, the etching process may also be an RIE process. Accordingly, the substrate may not need to leave the chamber in which the preferential etching process is implemented. This improves throughput and reduces complexity of the process. Further processing may result in the patterned feature 310 being transferred into the layer 301 as well.

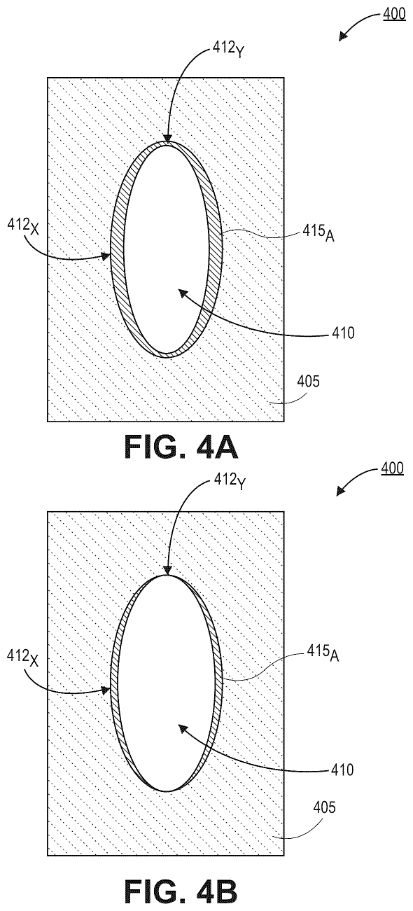

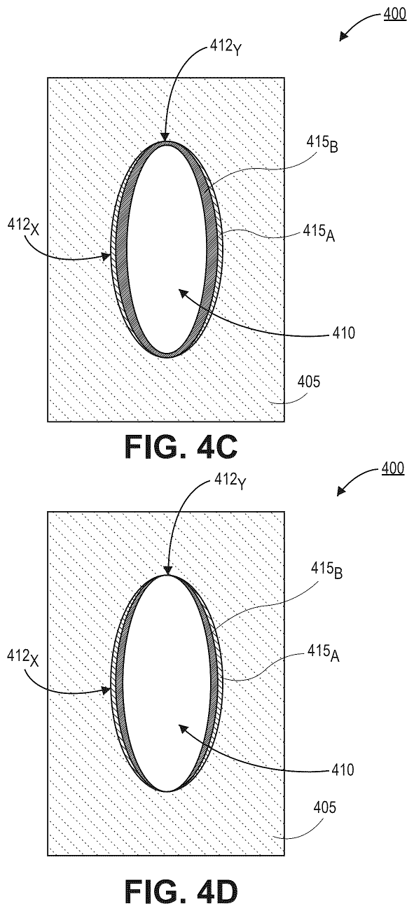

Referring now to FIGS. 4A-4D, a series of plan view illustrations depicting a multi-cycle process for selective deposition is shown, in accordance with an embodiment.

Referring now to FIG. 4A, a plan view illustration of a substrate 400 is shown, in accordance with an embodiment. In an embodiment, the substrate 400 may comprise a layer 405 with a patterned feature 410 formed through a thickness of the layer 405. In an embodiment, the patterned feature 410 has a height (top to bottom in FIG. 4A) that is greater than a width (left to right in FIG. 4A). In an embodiment, a directional deposition process has been used to deposit a second layer 415 A along sidewalls 412 of the patterned feature 410. The directional deposition process may be selective to the X-direction (i.e., left to right in FIG. 4A). As such, a thickness of the second layer 415_{A} along sidewalls 412_{X} may be greater than a thickness of the second layer 415_{A} along sidewalls 412_{Y}. The directional deposition process may be similar to the directional deposition process described in greater detail herein with respect to FIG. 1B.

Referring now to FIG. 4B, a plan view illustration of the substrate 400 after a preferential etching process is shown, in accordance with an embodiment. In an embodiment, the preferential etching process may be an RIE process. As such, loading effects resulting from the geometry of the patterned feature 410 may cause an uneven etch rate of the second layer 415_{A} along the sidewalls 412_{X} and the sidewalls 412_{Y}. Particularly, since the curvature of sidewalls 412_{X} is smaller than the curvature of sidewalls 412_{Y}, the sidewalls 412_{X} are more open and the second layer 415_{A} will etch faster along the sidewalls 412_{X} compared to the second layer 415_{A} along the sidewalls 412_{Y}. However, since the thickness of the second layer 415_{A} along sidewalls 412_{Y} was smaller, the slower etch rate may still result in the sidewalls 412_{Y} being exposed before the sidewalls 412_{X} are exposed.

Such an etching process may provide some preferential etching, but the overall reduction in the CD along the X-direction may not be as large as desired. Accordingly, one or more additional cycles of the selective deposition process may be implemented in order to provide the desired level of CD reduction in the X-direction.

Referring now to FIG. 4C, a plan view illustration of the substrate 400 after a second directional deposition process has been used to deposit a third layer 415_{B} along sidewalls 412 of the patterned feature 410 is shown, in accordance with an embodiment. The directional deposition process may be selective to the X-direction. As such, a thickness of the third layer 415_{B} along sidewalls 412_{X} may be greater than a thickness of the third layer 415_{B} along sidewalls 412_{Y}. The directional deposition process may be similar to the directional deposition process described in greater detail herein with respect to FIG. 1B.

Referring now to FIG. 4D, a plan view illustration of the substrate 400 after a second preferential etching process is shown, in accordance with an embodiment. In an embodiment, the second preferential etching process may also be an RIE process. As such, loading effects resulting from the geometry of the patterned feature 410 may cause an uneven etch rate of the third layer 415_{B} along the sidewalls 412_{X} and the sidewalls 412_{Y}. Particularly, since the curvature of sidewalls 412_{X} is smaller than the curvature of sidewalls 412_{Y}, the sidewalls 412_{X} are more open and the third layer 415_{B} will etch faster along the sidewalls 412_{X} compared to the third layer 415_{B} along the sidewalls 412_{Y}. However, since the thickness of the third layer 415_{B} along sidewalls 412_{Y} was smaller, the slower etch rate may still result in the sidewalls 412_{Y} being exposed before the third layer 415_{B} along sidewalls 412_{X} is fully removed.

As shown, the resulting substrate 400 now has a patterned feature 410 with a sidewalls 412_{X} that are lined by a second layer 415_{A} and a third layer 415_{B}, and the sidewalls 412_{Y} are exposed. Similar processes may be repeated any number of times in order to provide a desired number of layers along the sidewalls 412_{X}, while still keeping the sidewalls 412_{Y} substantially exposed (or with minimal coverage). Accordingly, the CD in the X-direction can be reduced without significantly changing the CD in the Y-direction.

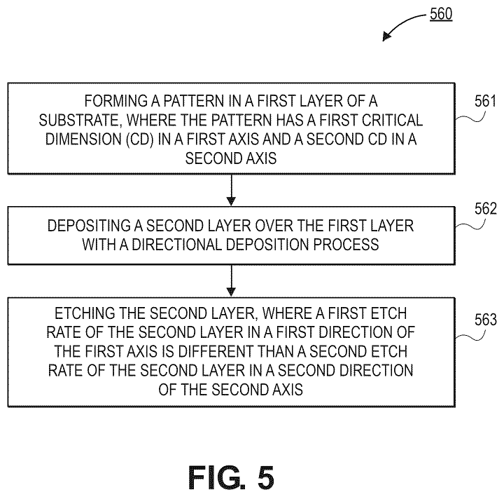

Referring now to FIG. 5, a flow diagram of a process for 560 for directionally depositing a layer along sidewalls of a patterned feature is shown, in accordance with an embodiment. In an embodiment, the process 560 may begin with operation 561, which comprises forming a pattern in a first layer of a substrate. In an embodiment, the pattern has a first CD in a first axis and a second CD in a second axis. The first CD may be different than the second CD in some embodiments. For example, the patterned may have an oblong shape, an oval shape, an elliptical shape, a rectangular shape, or the like. Though, other embodiments may also include a first CD that is substantially equal to the second CD, such as in a circle or a square. The pattern may be a hole that passes through an entire thickness of the first layer.

In an embodiment, the process 560 may continue with operation 562, which comprises depositing a second layer over the first layer with a directional deposition process. In an embodiment, the directional deposition process may preferentially deposit the second layer along sidewalls surfaces of the pattern that are substantially orthogonal to the first axis. That is, the first CD may be reduced to a greater extent than the second CD in some embodiments. In an embodiment, the directional deposition process may be similar to any of the directional deposition processes described in greater detail herein.

In an embodiment, the process 560 may continue with operation 563, which comprises etching the second layer, where a first etch rate of the second layer in a first direction of the first axis is different than a second etch rate of the second layer in a second direction of the second axis. In an embodiment, the etching may include an RIE process. As such, the geometry of the pattern may drive the uneven etch rates due to a loading mechanism, such as those described in greater detail herein.

In an embodiment, the process 560 may further comprise repeating operations 562 and 563 any number of times. For example, third layers, fourth layers, fifth layers, etc. may be directionally deposited and subsequently etched with a preferential etching process. Accordingly, embodiments may provide directional deposition processes with a selectivity that is 10:1 or greater, 100:1 or greater, 1,000:1 or greater, or even a truly 100% selective directional deposition.

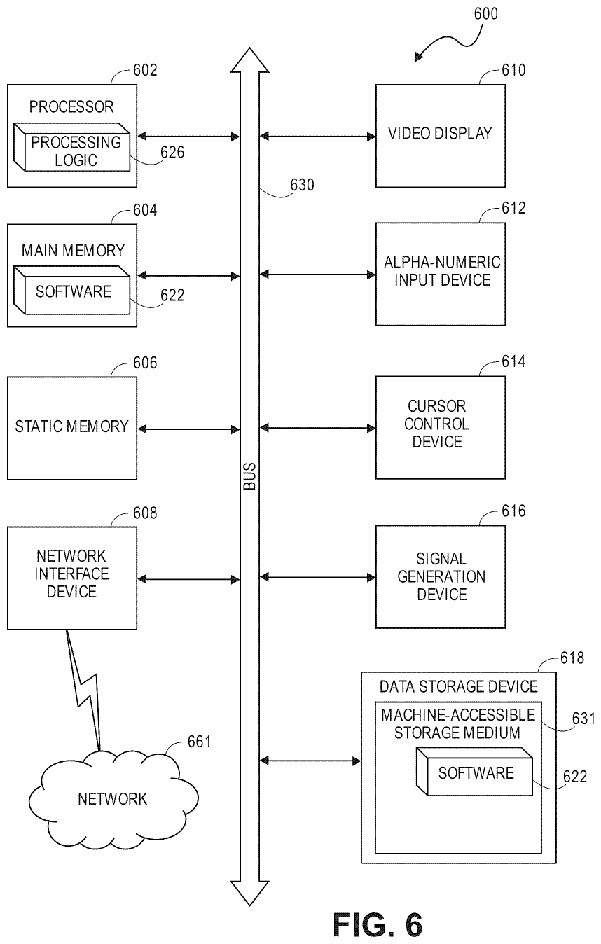

Referring now to FIG. 6, a block diagram of an exemplary computer system 600 of a processing tool is illustrated in accordance with an embodiment. In an embodiment, computer system 600 is coupled to and controls processing in a processing tool suitable for implementing one or more operations of a directional deposition process that includes an etch back operation in order to enable directional deposition with a selectivity that is 10:1 or greater, 100:1 or greater, 1,000:1 or greater, or even a truly 100% selective directional deposition.

Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 631 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 661 via the system network interface device 608. In an embodiment, the network interface device 608 may operate using RF coupling, optical coupling, acoustic coupling, or inductive coupling.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

Thus, embodiments of the present disclosure comprise directional deposition processes that include an etch back operation in order to enable directional deposition with a selectivity that is 10:1 or greater, 100:1 or greater, 1,000:1 or greater, or even a truly 100% selective directional deposition.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

What is claimed is:

1. A method, comprising:
forming a pattern in a first layer of a substrate, wherein the pattern has a first critical dimension (CD) in a first axis and a second CD in a second axis, and wherein the first CD is different than the second CD;
depositing a second layer over the first layer with a directional deposition process; and
etching the second layer, wherein a first etch rate of the second layer in a first direction of the first axis is different than a second etch rate of the second layer in a second direction.

2. The method of claim 1, wherein the etching process is a reactive ion etching (RIE) process.

3. The method of claim 1, wherein the first CD is greater than the second CD.

4. The method of claim 1, wherein the second CD is greater than the first CD.

5. The method of claim 1, wherein the directional deposition process is oriented to deposit a thicker portion of the second layer over a sidewall of the pattern in the first direction and a thinner portion of the second layer over the sidewall of the pattern in the second direction.

6. The method of claim 5, wherein the first etch rate is lower than the second etch rate.

7. The method of claim 1, wherein the second layer reduces the first CD of the pattern and the second CD remains constant after the etching.

8. The method of claim 1, further comprising:
depositing a third layer over the second layer with the directional deposition process after the etching; and
etching the third layer, wherein a third etch rate of the third layer in the first direction of the first axis is different than a fourth etch rate of the third layer in the second direction of the second axis.

9. The method of claim 1, wherein the second layer comprises one or more of carbon, oxygen, silicon, or nitrogen.

10. The method of claim 1, wherein the pattern is an oval.

11. A method comprising:
forming a pattern in a first layer of a substrate;
depositing a second layer over the first layer with a directional deposition process, wherein the second layer has a first thickness along a first sidewall portion of the pattern and a second thickness along a second sidewall portion of the pattern, and wherein the first thickness is greater than the second thickness; and
etching the second layer so that the second layer is completely removed from the second sidewall portion of the pattern while still remaining on the first sidewall portion of the pattern.

12. The method of claim 11, wherein the etching comprises a reactive ion etching (RIE) process.

13. The method of claim 11, wherein the pattern is transferred into the substrate after etching the second layer.

14. The method of claim 13, wherein etching the second layer and transferring the pattern into the substrate are performed in a single chamber.

15. The method of claim 11, wherein the second layer comprises one or more of carbon, oxygen, silicon, or nitrogen.

16. The method of claim 11, wherein the pattern has a first critical dimension (CD) in a first direction and a second CD in a second direction, wherein the first CD is different than the second CD.

17. The method of claim 11, further comprising:
repeating the operations of depositing the second layer with a directional deposition process and etching the second layer a plurality of times.

18. A method, comprising:
depositing a second layer over a first layer, wherein a hole is in the first layer, and wherein the second layer has a non-uniform thickness along a sidewall perimeter of the hole; and
etching the second layer with a reactive ion etching (RIE) process, wherein the second layer is cleared from a first portion of the sidewall of the hole, and wherein a second portion of the sidewall of the hole remains covered by the second layer.

19. The method of claim 18, wherein the hole has a first critical dimension (CD) and a second CD that is different than the first CD, and wherein a first thickness of the second layer on the sidewall of the hole in a first direction of the first CD is greater than a second thickness of the second layer on the sidewall of the hole in a second direction of the second CD.

20. The method of claim 19, wherein etching the second layer etches the second layer on the sidewall of the hole in the second direction faster than the second layer on the sidewall of the hole in the first direction.
